(19) United States
(12) Patent Application Publication
(10) Pub. No.: US 2026/0068702 A1
(43) Pub. Date: Mar. 5, 2026

(54) SEMICONDUCTOR STRUCTURE AND METHOD OF FORMING THE SAME

(71) Applicant: MEDIATEK INC., Hsinchu City (TW)

(72) Inventors: Cheng-Lin HUANG, Hsinchu City (TW); Tzu-Jui FANG, Hsinchu City (TW); Chien-Wei HUNG, Hsinchu City (TW)

(21) Appl. No.: 19/307,134

(22) Filed: Aug. 22, 2025

Related U.S. Application Data
(60) Provisional application No. 63/688,428, filed on Aug. 29, 2024.

(51) Int. Cl. H01L 23/538; H01L 23/00; H01L 25/065; H01L 25/16; H01L 25/18; H10B 80/00; H10D 80/30

(52) U.S. Cl. CPC H01L 23/5385; H10B 80/00; H10D 80/30

(57) ABSTRACT

A semiconductor package structure is provided. The semiconductor package structure includes a substrate, a first semiconductor die, a second semiconductor die, a bridge structure and a memory structure. The substrate includes a wiring structure disposed in dielectric layers. The first semiconductor die and the second semiconductor die are disposed over the substrate. The bridge structure is embedded in the substrate. The first semiconductor die is electrically coupled to the second semiconductor die through the bridge structure. Moreover, the memory structure is embedded in the substrate and is positioned below the bridge structure.

### CROSS REFERENCE TO RELATED APPLICATIONS

This application claims the benefit of U.S. Provisional Application No. 63/688,428 filed on Aug. 29, 2024, the entirety of which is incorporated by reference herein.

### BACKGROUND OF THE DISCLOSURE

### Field of the Disclosure

The present disclosure relates to semiconductor technology, and, in particular, it to a semiconductor package structure including a bridge structure.

### Description of the Related Art

In recent years, the demand for high-bandwidth and low-latency communication between semiconductor chips has increased significantly, especially in applications such as artificial intelligence (AI), high-performance computing (HPC), and data centers. To meet these requirements, advanced packaging technologies have been developed to integrate multiple chips within a single package, thereby reducing interconnect length and improving electrical performance.

A packaging solution involves using a bridge die to electrically connect multiple active semiconductor dies, such as a logic die and one or more memory dies, disposed side-by-side on a substrate. In such structures, the bridge die typically includes high-density interconnects and is embedded or disposed within a redistribution layer (RDL) or within the substrate itself. The bridge die allows for fine-pitch signal routing between the adjacent active dies, enabling higher signal integrity and bandwidth compared to conventional substrate routing.

Although existing semiconductor package structure using bridge dies have been adequate for their intended purposes, they have not been entirely satisfactory in all respects. For example, the number and arrangement of chips, particularly memory dies, that can be effectively integrated within a single package are often limited by factors such as available routing area, bridge die placement constraints, and signal integrity considerations. This limits the achievable memory capacity within the package, which may be insufficient to meet the growing demands of memory-intensive applications.

Accordingly, there exists a need for an improved semiconductor package structure that can accommodate a greater number of memory dies, while maintaining high-speed interconnectivity, and design flexibility.

### BRIEF SUMMARY OF THE DISCLOSURE

In accordance with some embodiments of the present disclosure, a semiconductor package structure is provided. The semiconductor package structure includes a substrate, a first semiconductor die, a second semiconductor die, a bridge structure and a memory structure. The substrate includes a wiring structure disposed in dielectric layers. The first semiconductor die and the second semiconductor die are disposed over the substrate. The bridge structure is embedded in the substrate. The first semiconductor die is electrically coupled to the second semiconductor die through the bridge structure. Moreover, the memory structure is embedded in the substrate and positioned below the bridge structure.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1A and FIG. 1B are cross-sectional diagrams of an exemplary semiconductor package structure in accordance with some embodiments of the present disclosure;

FIG. 2 is an enlarged diagram of area A1 in FIG. 1A in accordance with some embodiments of the present disclosure;

FIG. 3A and FIG. 3B are enlarged diagrams of area A1 in FIG. 1A in accordance with some other embodiments of the present disclosure;

FIG. 4A and FIG. 4B are enlarged diagrams of area A2 in FIG. 2 in accordance with some embodiments of the present disclosure;

FIG. 5A and FIG. 5B are enlarged diagrams of area A1 in FIG. 1A in accordance with some other embodiments of the present disclosure;

FIG. 6 is a cross-sectional diagram of an exemplary semiconductor package structure in accordance with some other embodiments of the present disclosure.

### DETAILED DESCRIPTION OF THE INVENTION

The semiconductor package structure according to the present disclosure is described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In the following descriptions, terms “about”, “substantially” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “between the first value and the second value” means that the range includes the first value, the second value, and other values in between.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with the embodiments of the present disclosure, a semiconductor package structure is provided. The semiconductor package structure includes a memory structure embedded in a substrate and positioned below a bridge die. With such a configuration, the area utilization of the substrate can be improved, and the semiconductor package structure can provide increased memory capacity.

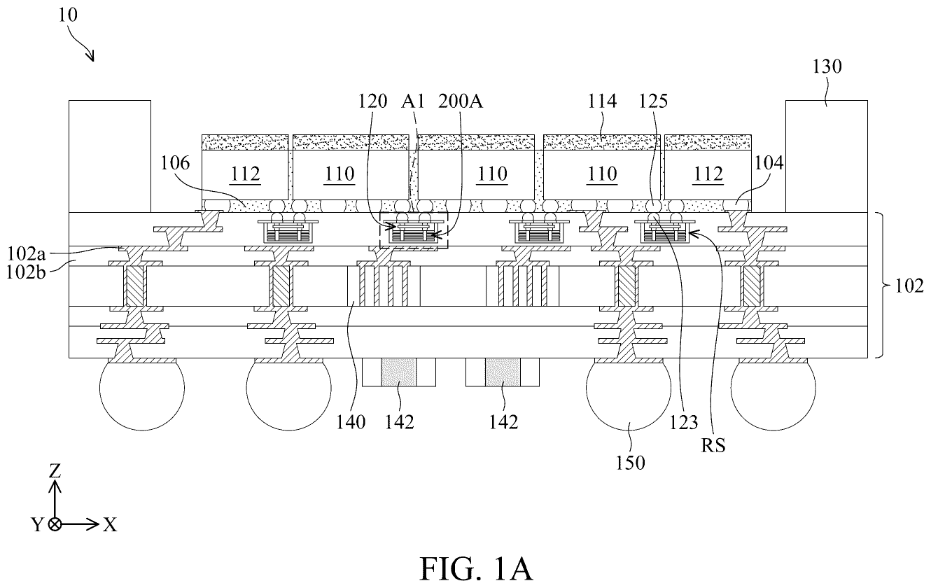

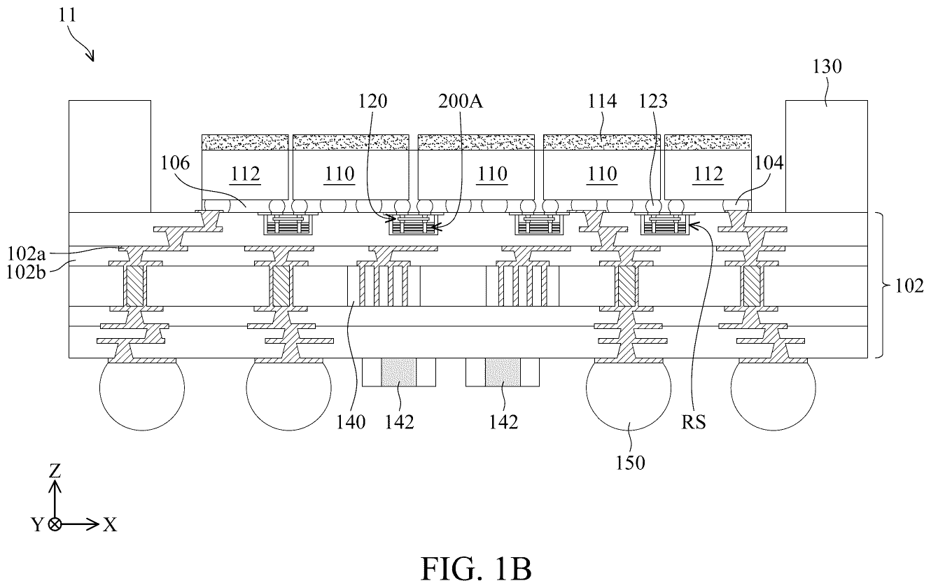

Please refer to FIG. 1A, which is a cross-sectional diagram of an exemplary semiconductor package structure 10 in accordance with some embodiments of the present disclosure. It should be understood that some elements of the semiconductor package structure 10 may be omitted in the figure for clarity, and only some elements are schematically illustrated. In accordance with some embodiments, additional features may be added to the semiconductor package structure 10 described below. In accordance with some other embodiments, some features of the semiconductor package structure 10 described below may be replaced or omitted.

As shown in FIG. 1A, the semiconductor package structure 10 includes a substrate 102. The substrate 102 includes a wiring structure 102a disposed in dielectric layers 102b. Specifically, the substrate 102 includes a plurality of dielectric layers 102b stacked on each other, and the wiring structure 102a is formed within the dielectric layers 102b. It should be understood that only parts of the wiring structure 102a and dielectric layers 102b are labeled for clarity.

In accordance with some embodiments, the wiring structure 120a includes conductive layers, conductive pads, conductive vias, conductive trenches, conductive pillars, the like, or a combination thereof. The conductive vias or conductive trenches may electrically couple different levels of the conductive layers. In accordance with some embodiments, the wiring structure 102a may be formed of metal, such as tungsten, titanium, tantalum, ruthenium, cobalt, copper, aluminum, platinum, tin, silver, gold, an alloy thereof, another suitable conductive material, or a combination thereof, but it is not limited thereto. The wiring structure 102a may be formed in the dielectric layers 102b by a plating process, a chemical vapor deposition (CVD) process, a physical vapor deposition (PVD) process, or another applicable process. In accordance with some embodiment, the metal material may be patterned through one or more photolithography processes and/or etching processes to form the wiring structure 120a. In accordance with some embodiments, the photolithography process may include photoresist coating (e.g., spin coating), soft baking, hard baking, mask alignment, exposure, post-exposure baking, photoresist development, cleaning and drying, etc. The etching process may include a dry etching process or a wet etching process.

In accordance with some embodiments, the dielectric layers 102b may be formed of organic polymer, including polyimide (PI), polybenzoxazole (PBO), benzocyclobutene (BCB), epoxy, Ajinomoto build-up film (ABF), Bismaleimide-Triazine (BT resin), another suitable organic dielectric material, or a combination thereof, but it is not limited thereto. The dielectric layers 102b may be formed by a spin coating process, a chemical vapor deposition (CVD) process, or another applicable process. In accordance with some embodiment, the dielectric layers 102b may be patterned through one or more photolithography processes and/or etching processes.

In accordance with some embodiments, the semiconductor package structure 10 includes a plurality of conductive connectors 104 and a plurality of conductive terminals 150 disposed on opposite sides of the substrate 102.

The conductive connectors 104 may be disposed above the substrate 102 and electrically coupled to the wiring structure 102a. The first semiconductor die 110 and the second semiconductor die 112 may be electrically coupled to the wiring structure 102a through the conductive connectors 104. The conductive connectors 104 may vertically overlap (for example, along the normal direction of the substrate 102) the wiring structure 102a and the first semiconductor die 110 or the second semiconductor die 112. In accordance with some embodiments, the conductive connectors 104 may be formed of metal, such as cobalt, copper, platinum, tin, silver, gold, another suitable conductive material, an alloy thereof, or a combination thereof, but it is not limited thereto. In accordance with some embodiments, the conductive connectors 104 may be bump elements, including microbumps, controlled collapse chip connection (C4) bumps, solder balls, ball grid array (BGA) balls, another suitable conductive connector, or a combination thereof. The conductive connector 104 may be formed as a bump element through a reflow process.

In accordance with some embodiments, the semiconductor package structure 10 may further include an underfill material (not illustrated) surrounding the conductive connectors 104. The underfill material may be disposed between the first semiconductor die 110 and the substrate 102 and/or between the second semiconductor die 112 and the substrate 102 and fill in gaps between the conductive connectors 104 to provide structural support. In accordance with some embodiments, the underfill material may include polymer, such as epoxy or another suitable material. In accordance with some embodiments, the underfill material may be dispensed with capillary force, and then may be cured through any suitable curing process.

The conductive terminals 150 may be disposed below the substrate 102 and electrically coupled to the wiring structure 102a. In accordance with some embodiments, the conductive terminals 150 may be further electrically coupled to an electronic component (not illustrated), and the wiring structure 102a may be electrically coupled to the electronic component through the conductive terminals 150. In accordance with some embodiments, the electronic component may include a printed circuit board (PCB), a chip, a control component or another electronic component, but it is not limited thereto. The conductive terminals 150 may vertically overlap the wiring structure 102a and the electronic component. In accordance with some embodiments, the conductive terminal 150 may be formed of metal, such as cobalt, copper, platinum, tin, silver, gold, another suitable conductive material, an alloy thereof, or a combination thereof, but it is not limited thereto. In accordance with some embodiments, the conductive terminals 150 may be bump elements, including microbumps, controlled collapse chip connection (C4) bumps, solder balls, ball grid array (BGA) balls, another suitable conductive connector, or a combination thereof. The conductive terminals 150 may be formed as a bump element through a reflow process.

In accordance with some embodiments, the semiconductor package structure 10 further includes one or more first passive components 140 disposed in the substrate 102. In accordance with some embodiments, the first passive component 140 may include a resistor, a capacitor, an inductor, or another suitable passive component. In accordance with some embodiments, the first passive component 140 may be disposed within one or more dielectric layers 102b and electrically coupled to the wiring structure 102a.

In accordance with some embodiments, the semiconductor package structure 10 further includes one or more second passive components 142 disposed on below the substrate 102. The second passive components 142 may be disposed on the lower surface of the substrate 102 and adjacent to the conductive terminal 150. In accordance with some embodiments, the second passive components 142 may include a resistor, a capacitor, an inductor, or another suitable passive component. In accordance with some embodiments, the second passive components 142 may be electrically coupled to the wiring structure 102a.

Moreover, as shown in FIG. 1A, the semiconductor package structure 10 includes one or more first semiconductor dies 110 and second semiconductor dies 112 disposed over the substrate 102. The first semiconductor die 110 and the second semiconductor die 112 may be disposed on the upper surface of the substrate 102 and electrically coupled to the wiring structure 102a. The first semiconductor die 110 and the second semiconductor die 112 may vertically overlap the wiring structure 102a. In accordance with some embodiments, the second semiconductor dies 112 may surround the first semiconductor die 110.

In accordance with some embodiments, the first semiconductor die 110 and the second semiconductor die 112 each independently includes a system-on-chip (SoC) die, a logic device, a memory device, a radio frequency (RF) device, the like, or any combination thereof. For example, the first semiconductor die 110 and the second semiconductor die 112 may each include a micro control unit (MCU) die, a microprocessor unit (MPU) die, a power management integrated circuit (PMIC) die, a radio frequency front end (RFFE) die, an accelerated processing unit (APU) die, a central processing unit (CPU) die, a graphics processing unit (GPU) die, an input-output (IO) die, a dynamic random access memory (DRAM) controller, a static random-access memory (SRAM), a high-bandwidth memory (HBM), an application processor (AP) die, an application specific integrated circuit (ASIC) die, the like, or any combination thereof.

The first semiconductor die 110 and the second semiconductor die 112 may include the same or different types of dies. For example, in accordance with some embodiments, the first semiconductor die 110 and the second semiconductor die 112 may include SoC dies. In accordance with some embodiments, the first semiconductor die 110 may include an ASIC die, and the second semiconductor die 112 may include a HBM die.

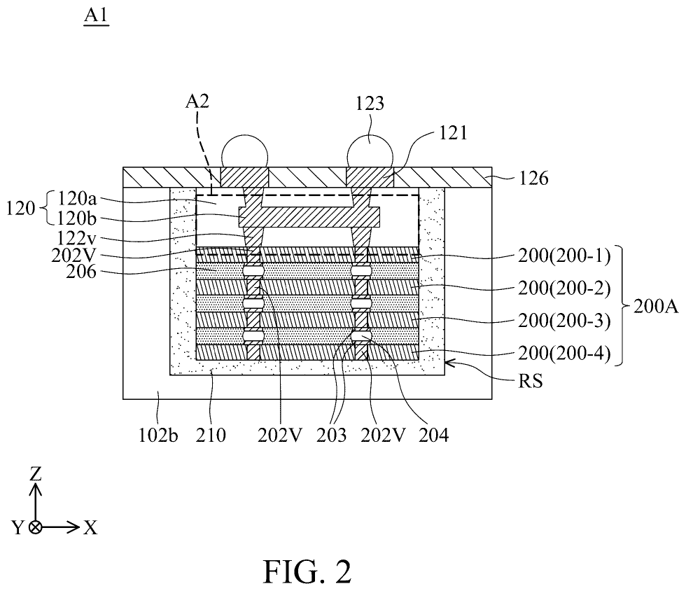

Please refer to FIG. 1A and FIG. 2. FIG. 2 is an enlarged diagram of area A1 in FIG. 1A in accordance with some embodiments of the present disclosure. The semiconductor package structure 10 includes one or more bridge structures 120 embedded in the substrate 102. The first semiconductor die 110 may be electrically coupled to the second semiconductor die 112 through the bridge structure 120. In accordance with some embodiments, one first semiconductor die 110 may be electrically coupled to another first semiconductor die 110 through the bridge structure 120. In accordance with some embodiments, the bridge structure 120 may be disposed in a recess RS formed in the upper portion of the dielectric layer 102b. In accordance with some embodiments, the bridge structure 120 and the memory structure 200A are embedded in the uppermost dielectric layer 102b of the substrate 102. In accordance with some embodiments, the bridge structure 120 may vertically overlap the first semiconductor die 110 and the second semiconductor die 112. In accordance with some embodiments, the bridge structure 120 may vertically overlap at least two first semiconductor dies 110. The bridge structure 120 may be a bridge die. Specifically, the bridge structure 120 may include a silicon body 120a and an interconnect structure 120b embedded in the silicon body 120a. The interconnect structure 120b may include a plurality of metal lines and vias disposed in one or more dielectric layers formed in the silicon body 102b, and the interconnect structure 120b may electrically couple a plurality of semiconductor dies to each other.

In addition, in accordance with some embodiments, the semiconductor package structure 10 may further include conductive pads 121, conductive connectors 123, conductive connectors 125 and a passivation layer 126 disposed on the bridge structure 120. In accordance with some embodiments, the interconnect structure 120b of the bridge structure 120 may be electrically coupled to the conductive connector 123 through the conductive pad 121 that penetrates the passivation layer 126. Moreover, in accordance with some embodiments, the conductive connectors 123 may be electrically coupled to the conductive connectors 125, and the interconnect structure 120b of the bridge structure 120 thereby may be electrically coupled to the first semiconductor die 110 and the second semiconductor die 112.

In accordance with some embodiments, the conductive pads 121 may be formed of metal, such as tungsten, titanium, tantalum, ruthenium, cobalt, copper, aluminum, platinum, tin, silver, gold, another suitable conductive material, an alloy thereof, or a combination thereof, but it is not limited thereto. The conductive pads 121 may be formed by a plating process, a chemical vapor deposition (CVD) process, a physical vapor deposition (PVD) process, or another applicable process.

In accordance with some embodiments, the passivation layer 126 may cover edge portions of the conductive pads 121 and may partially expose the conductive pads 121. In accordance with some embodiments, the passivation layer 126 may include a polymer layer, which may be formed of polyimide (PI), polybenzoxazole (PBO), benzocyclobutene (BCB), epoxy, another suitable polymer material, or a combination thereof, but it is not limited thereto. Alternatively, in accordance with some embodiments, the passivation layer 126 may include a dielectric layer, which may be formed of silicon oxide, silicon nitride, silicon oxynitride, another suitable dielectric material, or a combination thereof, but it is not limited thereto. The passivation layer 126 may be formed by a spin coating process, a chemical vapor deposition (CVD) process, or another applicable process.

In accordance with some embodiments, the conductive connectors 123 and the conductive connectors 125 may be formed of metal, such as cobalt, copper, platinum, tin, silver, gold, another suitable conductive material, an alloy thereof, or a combination thereof, but it is not limited thereto. In accordance with some embodiments, the conductive connectors 123 and the conductive connectors 125 may be bump elements, including microbumps, controlled collapse chip connection (C4) bumps, solder balls, ball grid array (BGA) balls, another suitable conductive connector, or a combination thereof. The conductive connectors 123 and the conductive connectors 125 may be formed as bump elements through a reflow process. In certain embodiments, the conductive connectors 125 may be omitted and replaced by the conductive connectors 123, i.e., utilizing the conductive connectors 123 to directly and electrically connected to the first semiconductor die 110 and the second semiconductor die 120, as illustrated in FIG. 1B. As illustrated in FIG. 1A or FIG. 1B, the conductive connectors 123 and/or the conductive connectors 123 may have a width smaller than the conductive connectors 104, allowing a higher routing density for the bridge structure 120 connected in between the first semiconductor die 110 and the second semiconductor die 120.

Moreover, as shown in FIG. 1A and FIG. 2, the semiconductor package structure 10 includes a memory structure 200A embedded in the substrate 102 and positioned below the bridge structure 120. Specifically, the memory structure 200A may be disposed in the recess RS formed in the upper portion of the dielectric layer 102b together with the bridge structure 120. In accordance with some embodiments, the bridge structure 120 vertically overlaps the memory structure 200A. In accordance with some embodiments, the memory structure 200A vertically overlaps the first semiconductor die 110 and the second semiconductor die 112. In accordance with some embodiments, the sidewalls of the silicon body 120a may be aligned with the sidewalls of the memory structure 200A. In accordance with some embodiments, the sidewalls of the silicon body 120a may be coplanar with the sidewalls of the memory structure 200A.

The memory structure 200A may be electrically coupled to the bridge structure 120. In accordance with some embodiments, the bridge structure 120 may include a conductive via 122V that penetrates the silicon body 120a and is electrically coupled to the interconnect structure 120b, and the memory structure 200A may be electrically coupled to the bridge structure 120 through the conductive via 122V. In accordance with some embodiments, the conductive via 122V may be formed of metal, such as copper, tungsten, tantalum, titanium, another suitable conductive material, an alloy thereof, or a combination thereof, but it is not limited thereto. In accordance with some embodiments, the conductive via 122V may be formed by a plating process, a chemical vapor deposition (CVD) process, a physical vapor deposition (PVD) process, or another applicable process. Specifically, a portion of the silicon body 120a may be removed to form a through hole by one or more photolithography processes and/or etching processes, and then the conductive material may be formed in the through hole by a plating process, a CVD process, a PVD process, or another applicable process.

In accordance with some embodiments, the memory structure 200A may include a plurality of memory dies 200 arranged in a stacked manner. As shown in FIG. 2, in accordance with some embodiments, the memory structure 200A may include four memory dies 200, and they are labeled as memory dies 200-1, 200-2, 200-3 and 200-4 for clarity. Specifically, in accordance with some embodiments, the memory structure 200A may be a high-bandwidth memory (HBM) structure, and each memory die 200 may be a dynamic random-access memory (DRAM) chip. In embodiments where the memory structure 200A is a HBM structure, the memory structure 200A may further include a base die (not shown) on which the memory dies 200 are stacked, where the base die is operable to control I/O interfaces of memory dies. In certain embodiments, the base die may be omitted, and the bridge structure 120 may additionally include similar functionalities of the base die, such that the bridge structure 120 together with the memory structure 200A can serve as the HBM structure. In accordance with some embodiments, the memory dies 200 may be interconnected through a plurality of conductive vias 202V. For example, the memory dies 200-1, 200-2, 200-3 and 200-4 may each include a conductive via 202V. The conductive vias 202V may be through-silicon vias (TSVs). The material and method of forming the conductive via 202V may be the same as or similar to those of the conductive via 122V, and thus are not repeated herein.

Moreover, in accordance with some embodiments, one of the conductive vias 202V may be electrically coupled to another conductive via 202V through a conductive connector 204, and the conductive connector 204 may be disposed between the conductive vias 202V and vertically overlap them. In accordance with some embodiments, the conductive connector 204 may be formed of metal, such as cobalt, copper, platinum, tin, silver, gold, another suitable conductive material, an alloy thereof, or a combination thereof, but it is not limited thereto. In accordance with some embodiments, the conductive connector 204 may be a bump element, including a microbump, a controlled collapse chip connection (C4) bump, a solder ball, a ball grid array (BGA) ball, another suitable conductive connector, or a combination thereof. The conductive connector 204 may be formed as a bump element through a reflow process. In accordance with some embodiments, the conductive connector 204 may be a hybrid bond element. The conductive connector 204 may be formed as a hybrid bond element through a hybrid bonding process involving dielectric and metal bonding.

In accordance with some embodiments, the memory structure 200A may further include an underfill material 206 surrounding the conductive connector 204. The underfill material 206 may be disposed between the memory dies 200 and fill in gaps between the conductive connectors 204 to provide structural support. In accordance with some embodiments, the underfill material 206 may include polymer, such as epoxy or another suitable material. In accordance with some embodiments, the underfill material 206 may be dispensed with capillary force, and then may be cured through any suitable curing process.

It should be understood that the number of the memory dies 200 in the memory structure 200A illustrated in FIG. 2 is exemplary, the memory structure 200A may have other suitable numbers of memory dies 200 in accordance with some other embodiments. For example, the memory structure 200A may have one, two, four, eight, twelve memory dies 200, but it is not limited thereto.

In accordance with some embodiments, the semiconductor package structure 10 may further include an encapsulating material 210 disposed in the recess RS of the dielectric layer 102b. The encapsulating material 210 may surround the bridge structure 120 and the memory structure 200A, which can reduce the effect of water and oxygen in the external environment on the bridge structure 120 and/or the memory structure 200A. In accordance with some embodiments, the encapsulating material 210 may be in contact with the bridge structure 120, the memory structure 200A and the passivation layer 126. In accordance with some embodiments, the encapsulating material 210 may include molding compound, epoxy, another suitable encapsulation material, or a combination thereof, but it is not limited thereto. In accordance with some embodiments, the encapsulating material 210 may be formed by a compression molding process, a transfer molding process, another applicable process, or a combination thereof. In accordance with some embodiments, the encapsulating material 210 may undergo a molding process in a liquid or semi-liquid state, and then be cured.

Please refer to FIG. 1A again. In accordance with some embodiments, the semiconductor package structure 10 may further include an encapsulating material 106 disposed over the substrate 102. The encapsulating material 106 may surround the first semiconductor die 110 and the second semiconductor die 112, which can reduce the effect of water and oxygen in the external environment on the first semiconductor die 110 and/or the second semiconductor die 112. In accordance with some embodiments, the encapsulating material 106 may be in contact with the first semiconductor die 110, the second semiconductor die 112, and there may be underfill (not illustrated) surrounding the conductive connector 104. The material and method of forming the encapsulating material 106 may be the same as or similar to those of the encapsulating material 210, and thus are not repeated herein.

In accordance with some embodiments, the semiconductor package structure 10 may further include a thermal interface material 114 disposed over the first semiconductor die 110 and the second semiconductor die 112. The thermal interface material 114 may be in contact with the backside of the first semiconductor die 110 and the second semiconductor die 112. In accordance with some embodiments, the thermal interface material 114 may be formed of thermal grease, thermal gel, thermal conductive adhesive, phase change material, phase change metal alloy, metal, polymer, another suitable material, or a combination thereof, but it is not limited thereto. In accordance with some embodiments, the sidewalls of the thermal interface material 116 may be substantially aligned with the sidewalls of the first semiconductor die 110 and/or the second semiconductor die 112. In accordance with some embodiments, the thermal interface material 114 may be formed by a printing process, a coating process, a compression molding process, a transfer molding process, a dispensing process, another applicable process, or a combination thereof.

In accordance with some embodiments, the semiconductor package structure 10 may further include a ring structure 130 disposed over the substrate 102. In accordance with some embodiments, the ring structure 130 may be attached to the substrate 102 through an adhesive layer (not illustrated). The ring structure 130 may be disposed along the sidewalls of the substrate 102 to reduce warpage, prevent bending, and maintain planarity of the substrate 102. The ring structure 130 may also provide structural integrity and underfill confinement. The ring structure 130 may surround the first semiconductor die 110 and the second semiconductor die 112. In accordance with some embodiments, the ring structure 130 may include molding compound, epoxy, metal, another suitable material, or a combination thereof, but it is not limited thereto. In accordance with some embodiments, the ring structure 130 may be formed by a compression molding process, a transfer molding process, a dispensing process, a PVD process, another applicable process, or a combination thereof.

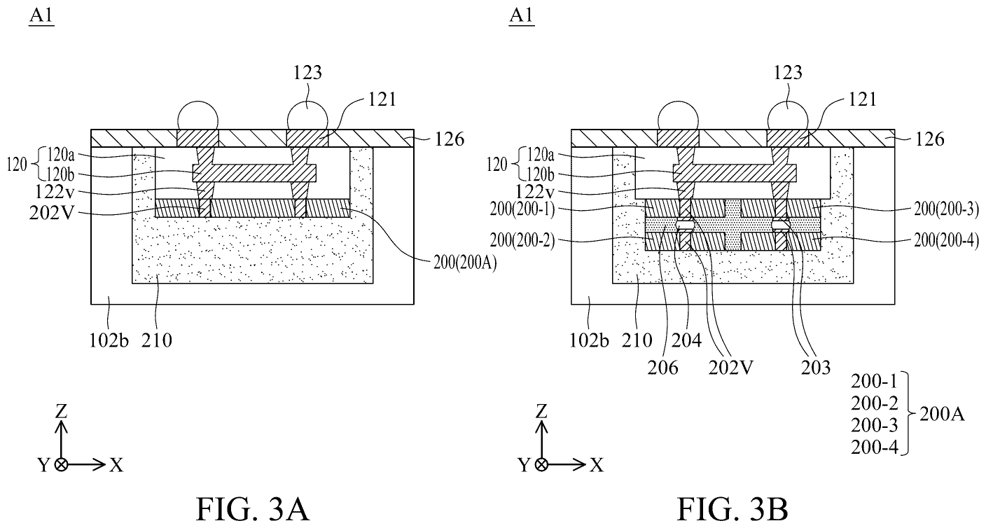

Please refer to FIG. 3A and FIG. 3B, which are enlarged diagrams of area A1 in FIG. 1A in accordance with some other embodiments of the present disclosure. The memory structure 200A may have different configurations in accordance with other embodiments. As shown in FIG. 3A, the memory structure 200A includes a single memory die 200, in accordance with some embodiments. As shown in FIG. 3B, the memory structure 200A includes a plurality of memory dies 200-1, 200-2, 200-3 and 200-4, the memory dies 200-1 and 200-2 are stacked in a stacked manner, and the memory dies 200-3 and 200-4 are stacked in a stacked manner. Moreover, memory die 200-1 may be disposed laterally adjacent to memory die 200-3 on the same level, and memory die 200-2 may be disposed laterally adjacent to memory die 200-4 on the same level, wherein the latter level is different from that of memory dies 200-1 and 200-3. Memory die 200-1 and memory die 200-3 may be physically distinct and spaced apart from each other. Memory die 200-2 and memory die 200-4 may be physically distinct and spaced apart from each other.

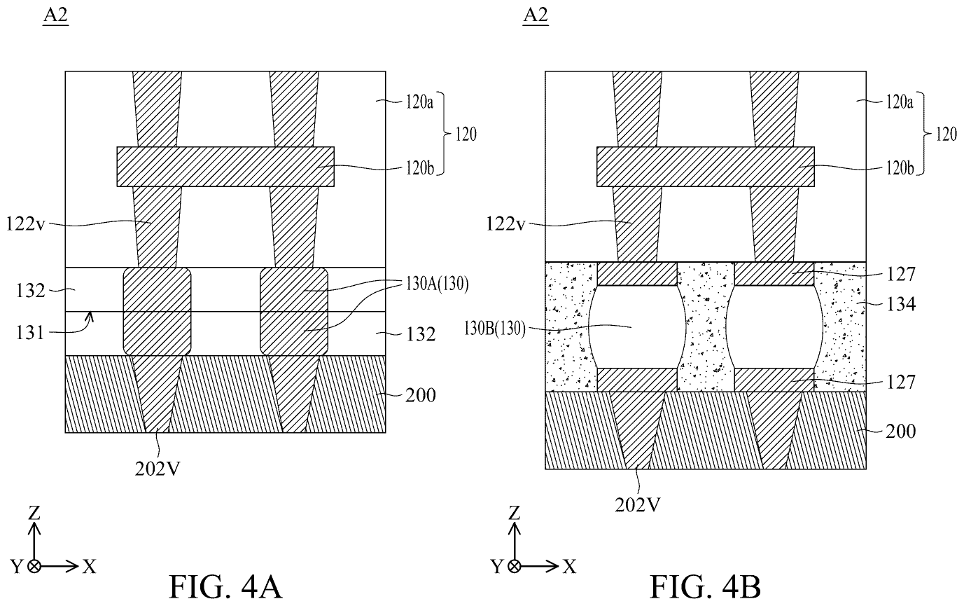

Please refer to FIG. 4A and FIG. 4B, which are enlarged diagrams of area A2 in FIG. 2 in accordance with some embodiments of the present disclosure. The detailed connection between the bridge structure 120 and the memory die 200 of the memory structure 200A are illustrated in FIG. 4A and FIG. 4B. The bridge structure 120 may be electrically coupled to the memory die 200 of the memory structure 200A through a conductive connector 130.

As shown in FIG. 4A, the conductive connector 130 may be a hybrid bond element 130A in accordance with some embodiments. Specifically, the interconnect structure 120b of the bridge structure 120 may be electrically coupled to the memory die 200 through the conductive via 122V, the hybrid bond elements 130A and the conductive via 202V, in accordance with some embodiments. The hybrid bond elements 130A may be disposed between the conductive via 122V and the conductive via 202V. The hybrid bond elements 130A may vertically overlap the conductive via 122V and the conductive via 202V. The hybrid bond elements 130A may be formed through a hybrid bonding process. More specifically, a hybrid bonding process may be performed to bond metal materials and dielectric materials together, thereby forming hybrid bond elements 130A and bonded dielectric elements 132 at the bonding interface 131. The dielectric elements 132 may be disposed between the silicon body 120a and the memory die 200. In accordance with some embodiments, the hybrid bond element 130A may be formed of metal material, such as cobalt, copper, platinum, tin, silver, gold, another suitable conductive material, an alloy thereof, or a combination thereof, but it is not limited thereto. In accordance with some embodiments, the dielectric elements 132 may be formed of dielectric material, such as silicon oxide silicon oxide, silicon nitride, silicon oxynitride, another suitable low-k dielectric material, or a combination thereof, but it is not limited thereto.

On the other hand, as shown in FIG. 4B, the conductive connector 130 may be a bump element 130B in accordance with some embodiments. Specifically, the interconnect structure 120b of the bridge structure 120 may be electrically coupled to the memory die 200 through the conductive via 122V, the bump elements 130B and the conductive via 202V, in accordance with some embodiments. The bump elements 130B may be disposed between the conductive via 122V and the conductive via 202V. The bump elements 130B may vertically overlap the conductive via 122V and the conductive via 202V. The bump elements 130B may be merged together. In accordance with some embodiments, the bump elements 130B may be electrically coupled to the conductive via 122V through a conductive pad 127 of the bridge structure 120, and the bump elements 130B may be electrically coupled to the conductive via 202V through a conductive pad 127 of the memory die 200. In accordance with some embodiments, the bump elements 130B may be formed of metal, such as cobalt, copper, platinum, tin, silver, gold, another suitable conductive material, an alloy thereof, or a combination thereof, but it is not limited thereto. In accordance with some embodiments, the bump elements 130B may include a microbump, a controlled collapse chip connection (C4) bump, a solder ball, a ball grid array (BGA) ball, another suitable conductive connector, or a combination thereof. The bump elements 130B may be formed through a reflow process.

Moreover, an underfill material 134 may surround the bump elements 130B. The underfill material 134 may be disposed between the silicon body 120a and the memory die 200. The underfill material 134 may be disposed between the silicon body 120a and the memory die 200 and fill in gaps between the bump elements 130B to provide structural support. In accordance with some embodiments, the underfill material 134 may include polymer, such as epoxy or another suitable material. In accordance with some embodiments, the underfill material 134 may be dispensed with capillary force, and then may be cured through any suitable curing process.

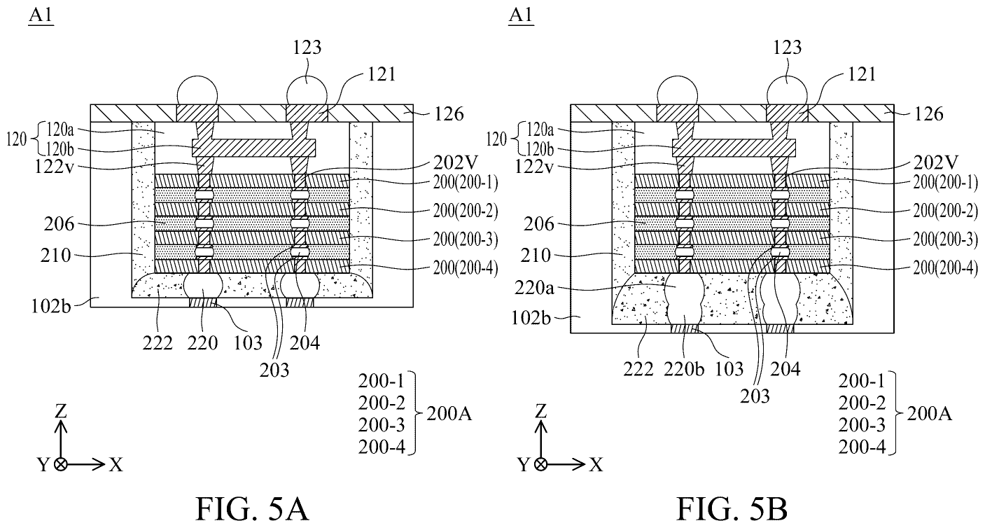

Next, refer to FIG. 5A and FIG. 5B, which are enlarged diagrams of area A1 in FIG. 1A in accordance with some other embodiments of the present disclosure. In accordance with some embodiments, the memory structure 200A may be electrically coupled to one or more conductive elements 103 in the wiring structure 102a of the substrate 102. In other words, the bridge structure 120 may be electrically coupled to the memory structure 200A, and then electrically coupled to the wiring structure 102a of the substrate 102, in accordance with some embodiments. In accordance with some embodiments, the conductive element 103 may be a conductive pad located at an upper portion of the wiring structure 102a.

As shown in FIG. 5A, in accordance with some embodiments, the memory structure 200A may be electrically coupled to the conductive element 103 through the conductive via 202V penetrating the memory die 200 and a conductive connector 220. The conductive connector 220 may serve as a conductive terminal of the memory structure 200A. The conductive connector 220 may be disposed between the memory die 200 and the conductive element 103 of the wiring structure 102a. The conductive connector 220 may vertically overlap the conductive via 202V and the conductive element 103. In accordance with some embodiments, the conductive connector 220 may be a bump element, including a microbump, a controlled collapse chip connection (C4) bump, a solder ball, a ball grid array (BGA) ball, another suitable conductive connector, or a combination thereof. The conductive connector 220 may be formed as a bump element through a reflow process.

Moreover, in accordance with some embodiments, the semiconductor package structure 10 may further include an underfill material 222 surrounding the conductive connector 220 and the conductive element 103. The underfill material 222 may be in contact with the encapsulating material 210 surrounding the bridge structure 120 and the memory structure 200A. In accordance with some embodiments, the underfill material 222 may include polymer, such as epoxy or another suitable material. In accordance with some embodiments, the underfill material 222 may be dispensed with capillary force, and then may be cured through any suitable curing process.

As shown in FIG. 5B, in accordance with some embodiments, the memory structure 200A may be electrically coupled to the conductive element 103 through the conductive via 202V penetrating the memory die 200 and conductive connectors 220a and 220b. The conductive connector 220a may serve as a conductive terminal of the memory structure 200A. The conductive connectors 220a and 220b may be disposed between the memory die 200 and the conductive element 103 of the wiring structure 102a. The conductive connector 220a may vertically overlap the conductive via 202V, and the conductive connector 220b may vertically overlap the conductive element 103. In accordance with some embodiments, the conductive connectors 220a and 220b may be bump elements, including microbumps, controlled collapse chip connection (C4) bumps, solder balls, ball grid array (BGA) balls, another suitable conductive connector, or a combination thereof. The conductive connectors 220a and 220b may be formed as bump elements through a reflow process. The conductive connectors 220a and 220b may be merged together. In other words, the memory structure 200A may be electrically coupled to the conductive element 103 through a bump-to-bump connection, in accordance with some embodiments. Moreover, in accordance with some embodiments, the underfill material 222 may surround the conductive connectors 220a and 220b. The underfill material 222 may be disposed between the memory die 200 and the conductive element 103 and fill in gaps between the conductive connectors 220a and 220b to provide structural support. In addition, the underfill material 222 may be in contact with the encapsulating material 210 surrounding the bridge structure 120 and the memory structure 200A.

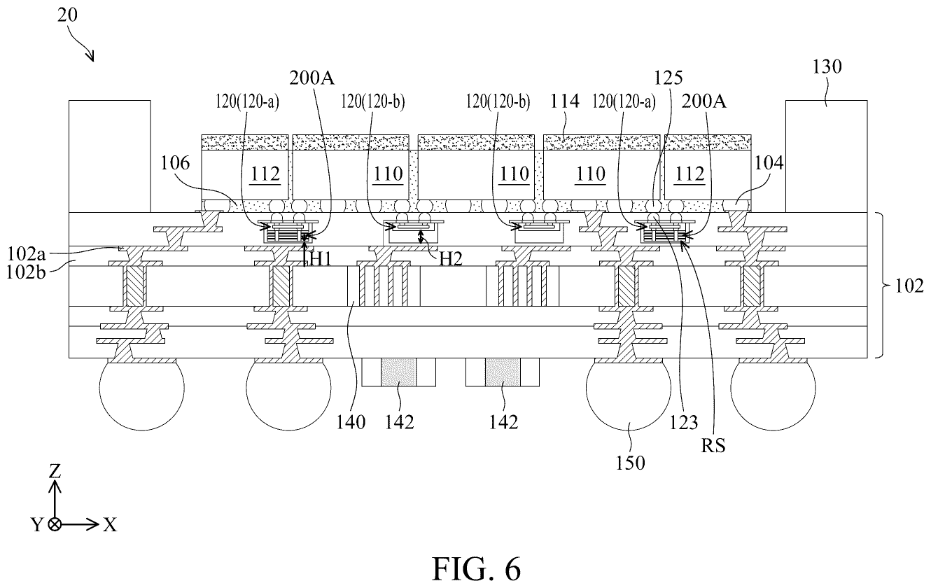

Please refer to FIG. 6, which is a cross-sectional diagram of an exemplary semiconductor package structure 20 in accordance with some other embodiments of the present disclosure. It should be understood that the same or similar components or elements in above and below contexts are represented by the same or similar reference numerals. The materials, manufacturing methods and functions of these components or elements are the same or similar to those described above, and thus will not be repeated in the following description.

As shown in FIG. 6, the semiconductor package structure 20 includes a plurality of bridge structures 120 embedded in the substrate 102, and the memory structures 200A may be positioned below some of the bridge structures 120. That is, in accordance with some embodiments, some of the bridge structures 120 (for clear explanation, also labeled as 120-a) vertically overlap the memory structure 200A, while some of the bridge structures 120 (for clear explanation, also labeled as 120-b) do not vertically overlap the memory structure 200A. In accordance with some embodiments, the encapsulating material 210 surrounding the bridge structure 120-a has a first bottom height H1, the encapsulating material 210 surrounding the bridge structure 120-b has a second bottom height H2, and the first height H1 is different from the second height H2. In accordance with some embodiments, the first height H1 is smaller than the second height H2. In accordance with some other embodiments (e.g., as shown in FIG. 1A), the first height H1 is substantially equal to the second height H2. Furthermore, in accordance with some embodiments, the encapsulating material 210 having the first bottom height H1 vertically overlaps with the first semiconductor die 110 and the second semiconductor die 112, and the encapsulating material 210 having the second bottom height H2 vertically overlaps with two first semiconductor dies 110. In accordance with some other embodiments, the encapsulating material 210 having the first bottom height H1 vertically overlaps with two first semiconductor dies 110, and the encapsulating material 210 having the second bottom height H2 vertically overlaps with the first semiconductor die 110 and the second semiconductor die 112.

It should be noted that the aforementioned first bottom height H1 and second bottom height H2 refer to the height of the encapsulating material 210 positioned below the memory structure 200A (when the bridge structure 120 overlaps the memory structure 200A), or the height of the encapsulating material 210 positioned below the bridge structure 120 (when the bridge structure 120 does not overlap the memory structure 200A).

To summarize the above, in accordance with the embodiments of the present disclosure, the provided semiconductor package structure includes a memory structure embedded in a substrate and positioned below a bridge die. With such a configuration, the area utilization of the substrate can be improved, and the semiconductor package structure can provide increased memory capacity.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package structure, comprising:
a substrate comprising a wiring structure disposed in dielectric layers;
a first semiconductor die and a second semiconductor die disposed over the substrate;
a bridge structure embedded in the substrate, wherein the first semiconductor die is electrically coupled to the second semiconductor die through the bridge structure; and
a memory structure embedded in the substrate and positioned below the bridge structure.

2. The semiconductor package structure as claimed in claim 1, wherein the bridge structure is electrically coupled to the memory structure through a first conductive connector.

3. The semiconductor package structure as claimed in claim 2, wherein the first conductive connector is a hybrid bond element.

4. The semiconductor package structure as claimed in claim 2, wherein the first conductive connector is a bump element.

5. The semiconductor package structure as claimed in claim 4, further comprising a first underfill material surrounding the bump element.

6. The semiconductor package structure as claimed in claim 1, wherein the bridge structure vertically overlaps the memory structure.

7. The semiconductor package structure as claimed in claim 1, wherein the memory structure vertically overlaps the first semiconductor die and the second semiconductor die.

8. The semiconductor package structure as claimed in claim 1, further comprising an encapsulating material surrounding the bridge structure and the memory structure.

9. The semiconductor package structure as claimed in claim 8, wherein the bridge structure comprises a first bridge structure and a second bridge structure, and a first bottom height of the encapsulating material surrounding the first bridge structure is different from a second bottom height of the encapsulating material surrounding the second bridge structure.

10. The semiconductor package structure as claimed in claim 9, wherein the first bridge structure vertically overlaps the memory structure while the second bridge structure does not vertically overlap the memory structure, and the first bottom height is smaller than the second bottom height.

11. The semiconductor package structure as claimed in claim 1, wherein the bridge structure comprises a silicon body, an interconnect structure embedded in the silicon body, and a first conductive via that penetrates the silicon body and is electrically coupled to the interconnect structure.

12. The semiconductor package structure as claimed in claim 11, wherein the first conductive via is electrically coupled to a second conductive via penetrating the memory structure.

13. The semiconductor package structure as claimed in claim 1, wherein the bridge structure and the memory structure are embedded in the uppermost dielectric layer of the substrate.

14. The semiconductor package structure as claimed in claim 1, wherein the memory structure comprises a plurality of memory dies arranged in a stacked manner, the plurality of memory dies are interconnected through a plurality of second conductive via, and one of the second conductive vias is electrically coupled to another second conductive via through a second conductive connector.

15. The semiconductor package structure as claimed in claim 14, further comprising a second underfill material surrounding the second conductive connector.

16. The semiconductor package structure as claimed in claim 1, wherein the memory structure comprises a first memory die and a second memory die, and the first memory die is disposed laterally adjacent to the second memory die on the same level.

17. The semiconductor package structure as claimed in claim 1, wherein the memory structure is electrically coupled to a conductive element in the wiring structure of the substrate.

18. The semiconductor package structure as claimed in claim 17, wherein the memory structure is electrically coupled to the conductive element through a second conductive via penetrating the memory structure and a third conductive connector.

19. The semiconductor package structure as claimed in claim 18, further comprising a third underfill material surrounding the third conductive connector, wherein the third underfill material is in contact with an encapsulating material surrounding the bridge structure and the memory structure.

20. The semiconductor package structure as claimed in claim 1, further comprising a plurality of conductive terminals disposed below the substrate and electrically coupled to the wiring structure.
